(19) United States
(12) Patent Application Publication
(10) Pub. No.: US 2011/0272786 A1
(43) Pub. Date: Nov. 10, 2011

(54) ENERGY STORAGE SYSTEM

(75) Inventors: Willem Frederik Adrianus Besling, Eindhoven (NL); Rogier Adrianus Henrica Niessen, Eindhoven (NL); Johan Hendrik Klootwijk, Eindhoven (NL); Nynke Verhaegh, Arnhem (NL); Petrus Henricus Laurentius Notten, Waalre (NL); Marcel Mulder, Eindhoven (NL)

(73) Assignee: NXP B.V., Eindhoven (NL)

(21) Appl. No.: 13/122,900

(22) PCT Filed: Sep. 25, 2009
(86) PCT No.: PCT/IB09/54192

§ 371 Date: Apr. 6, 2011

(30) Foreign Application Priority Data
Oct. 9, 2008 (EP) 08105538.6

(51) Int. Cl. H01L 27/06; H01L 21/02

(52) U.S. Cl. 257/534; 257/528; 438/381; 257/E27.013; 257/E21.003

(57) ABSTRACT

An energy storage device (300), the device (300) comprising a substrate (102), a steric structure (104) formed on and/or in a main surface (106) of the substrate (102), a current collector stack (202) formed on the steric structure (104), and an electric storage stack (302) formed on the current collector stack (202), wherein side walls (108) of the steric structure (104) and the main surface (106) of the substrate (102) enclose an acute angle of more than 80 degrees.

### FIELD OF THE INVENTION

The invention relates to an energy storage device and/or an electrochemical device.

Furthermore, the invention relates to an electronic apparatus.

Moreover, the invention relates to a method of manufacturing an energy storage device.

### BACKGROUND OF THE INVENTION

In electronics, a battery comprises an electrochemical cell which stores chemical energy which can be converted into electrical energy. The battery has become a common power source for many household and industrial applications.

WO 2005/027245 discloses an electrochemical energy source comprising at least one assembly of a first electrode, a second electrode, and an intermediate solid-state electrolyte separating said first electrode and said second electrode. The disclosure also relates to an electronic module provided with such an electrochemical energy source. The disclosure further relates to an electronic device provided with such an electrochemical energy source. Moreover, the disclosure relates to a method of manufacturing such an electrochemical energy source.

US 2008/0050656 discloses a monolithically integrated lithium thin film battery which provides increased areal capacity on a single level (without stacking of multiple cells). The lithium thin film battery comprises a substrate having a surface textured to comprise a plurality of openings having sides angled between 10 and 80 degrees to the surface. A current collector and a cathode are formed on the substrate and within the openings. An electrolyte comprising lithium phosphorous oxynitride is formed by physical vapor deposition on the cathode, thereby providing a layer on the surface of the cathode and within the openings of the cathode having substantially the same thickness. An anode and a capping layer are then formed on the electrolyte.

However, conventional energy storage devices may be still too large in size.

### OBJECT AND SUMMARY OF THE INVENTION

It is an object of the invention to enable appropriate energy storage with sufficiently small dimensions.

In order to achieve the object defined above, an energy storage device, an electronic apparatus and a method of manufacturing an energy storage device according to the independent claims are provided.

According to an exemplary embodiment of the invention, an energy storage device (for instance for storing electrochemical and/or electric energy, for instance in an electrochemical form) is provided, the device comprising a substrate, a steric structure (such as a three-dimensional structure formed by adding material to and/or by removing material from the substrate) formed on and/or in a main surface (which may be a planar surface portion) of the substrate, a current collector stack formed on (particularly directly on or separated by a barrier layer) the steric structure, and an electric storage stack formed on (particularly directly on) the current collector stack, wherein side walls (which may be formed within the substrate or which may protrude from the main surface) of the steric structure and the main surface of the substrate enclose an acute angle (that is the angle between side wall and main surface which is less or equal to 90 degrees) of more than (for instance about) 80 degrees.

According to another exemplary embodiment of the invention, an electronic apparatus is provided, comprising a functional component adapted for providing an electronic function when being powered with electric energy, and an energy storage device having the above mentioned features for storing the electric energy for powering the functional component. Such an electronic apparatus can be an integrated structure or may be a modular system formed by the functional component and the energy storage device.

According to still another exemplary embodiment of the invention, a method of manufacturing an energy storage device is provided, the method comprising forming a steric structure on and/or in a main surface of a substrate, forming a current collector stack on the steric structure, and forming an electric storage stack on the current collector stack, wherein side walls of the steric structure and the main surface of the substrate enclose an acute angle of more than about 80 degrees.

The term “substrate” may denote any suitable material, such as a semiconductor like silicon, a dielectric material like glass or plastic, or a metal or metallic foil like anodized aluminium, etc. According to an exemplary embodiment, the term “substrate” may be used to define generally the elements for layers that underlie and/or overlie a layer or portions of interest. Also, the substrate may be any other base on which a layer is formed.

The term “energy storage device” may particularly denote any physical structure which is capable of storing energy, for instance in an electric or in an electrochemical form.

The term “steric structure” may particularly denote any three-dimensional feature which can be designed on and/or in a substrate. A steric structure may particularly comprise recesses or holes formed in a substrate by removing material from the substrate. The term steric structure may also cover additional material components formed on top of a substrate such as a pillar or the like.

The term “isolation stack” may particularly denote a stacked arrangement of layers which can be used for electrical insulation from the substrate and or adhesion improvement of the layer(s) that are stacked on top.

The term “current collector stack” may particularly denote a stacked arrangement of layers which is used for current collection within the energy storage device. A current collector may be an inert structure of high electrical conductivity used to conduct current from or to an electric storage stack during discharge or charge.

The term “electric storage stack” may particularly denote a stack of layers which form components of the actual energy storage structure such as a battery. For example, an electric storage stack may comprise an anode, a cathode and an electrolyte layer in between when forming a battery. When forming a capacitor, such an electric storage stack may comprise two capacitor plates spaced by a dielectric.

The term “side walls” of the steric structure may particularly denote surface portions of the steric structure which have a component arranged in a vertical manner or perpendicular to the main surface of the substrate. Such sidewalls may be slanted with a constant or a spatially varying angular relationship to the main surface.

The term “main surface” of the substrate may particularly denote a planar surface portion of the substrate, particularly one which is commonly used for processing the substrate. For instance, when the substrate is a silicon wafer, the main surface of the silicon wafer is the surface of the silicon wafer which is commonly processed during microtechnology operations.

The term “acute angle of more than 80°” may particularly denote the smaller one of the two angles which are enclosed between a side wall and the main surface. Such an acute angle may be larger than 80°, particularly larger than 82°, more particularly larger than 84°, for instance 85°. The acute angle is smaller or equal to 90°, for instance smaller than 88° or smaller than 86°.

In the context of this application, the cathode may be denoted as the positive electrode and the anode may be denoted as the negative electrode, irrespective of whether the device is presently charged or discharged. In an embodiment, LiCoO₂ may be considered as the cathode, and the anode as the electrode where metallic lithium is oxidized during discharge and Li⁺ reduces to metallic lithium during charging.

The term “electrolyte” may particularly denote a medium which provides an ion transport mechanism between positive and negative electrodes of a cell and may simultaneously act as a dielectric insulator.

The term “dielectric layer” or a “dielectric insulator” may particularly denote a medium which separates charges between between positive and negative electrodes of a cell i.e. in particular a capacitor.

According to an exemplary embodiment of the invention, an energy storage device such as a battery is provided which can be monolithically integrated in a substrate and which has a large active surface on which energy can be stored. This can be made possible by providing the steric structure as a three-dimensional profile on or in the substrate and by depositing subsequently the layers contributing to the battery function on this steric structure. Hence, a three-dimensional geometry may be achieved with a significantly enlarged active area thereby significantly improving the energy storage performance of the system. The present inventors have surprisingly recognized that the provision of an acute angle of more than 80° can be made possible particularly by implementing physical vapour deposition and forming a layer sequence of deposited layers that have a significantly improved conformality on a sterically patterned substrate. This may improve the battery characteristic and may simultaneously result in reliable devices which are not prone to failure even under harsh conditions.

According to an exemplary embodiment of the invention, physical vapour deposition (PVD) may be used for growing solid state battery stacks or multi-layer capacitors in three dimensions particularly with a feature dimension of less than 20 μm. In an embodiment, a substrate biased sputter deposition may be used (for one or more of the layers in the complete stack). A corresponding battery may comprise a cathode current collector stack of SiO₂/TiO₂/Ti/Pt and a stack of LiCoO₂ cathode/Li₃PO₄ solid electrolyte/cobalt top-metallization. The total stack may have a dimension in the order of 2 micrometer (0.1 micrometer barrier layer, 0.1 micrometer anode, 0.5 micrometer solid state electrolyte, 1.0 micrometer cathode, 0.1 micrometer current collector). In an embodiment the stacks may be provided in a tapered trench of a substrate. This may allow to manufacture a full all-solid state battery in one PVD tool.

In an embodiment, an all-solid-state battery may be provided as a power buffer at low temperature. In such an all solid state 3D battery stack, all the battery layers may be manufactured specifically by PVD deposition such as magnetron sputtering or electron beam evaporation. The cathode current collector stack can be a stack out of the layers SiO₂, TiO₂, Ti and Pt, wherein Ti also can be sputtered. The battery layer sequence can be a stack of an LiCoO₂ cathode, a Li₃PO₄ solid electrolyte and a cobalt top metallization.

Embodiments of the invention relate to trenches with angle values between 80 degrees and 90 degrees, with an optimal angle being 85 degrees or more. Such angles are advantageous to guarantee a very large area enhancement while retaining/maintaining sufficient step coverage using PVD for 3D integrated batteries In other words, such angles are advantageous to guarantee a proper step coverage using PVD for 3D integrated batteries whereas these angles allow to maintain and achieve a very large area enhancement.

In the following, further exemplary embodiments of the energy storage device will be explained. However, these embodiments also apply to the electronic device and to the method of manufacturing an energy storage device.

The steric structure may comprise at least one trench (or one or more arrays of trenches) or pore formed in the substrate. For instance, a plurality of trenches may be formed in the substrate, for example by lithography and etching procedures. The aspect ratio of the trenches and the angular relationships between the side walls of the trench and a main surface of the substrate may have a significant influence on the quality and the reliability of such a structure. Examples for trench geometries are a rectangle, a trapezoid, a triangle, etc. Such a trench may have an aspect ratio (that is a ratio between depth and diameter of the trench) of larger than two, particularly of larger than five.

The steric structure may additionally or alternatively comprise at least one protrusion formed on the substrate. Such a protrusion or pillar may be a structure which extends from the main surface of the substrate and is formed for instance by layer deposition and etching. Alternatively, such protrusions may be formed by formed structures such as nanotubes or nanowires. Such protrusions have a similar effect as the trenches, namely to increase the active area of the energy storage. Examples for protrusion geometries are a rectangle, a trapezoid, a triangle, etc. Such a protrusion may have an aspect ratio (that is a ratio between vertical length and diameter of the protrusion) of larger than two, particularly of larger than five.

The current collector stack and/or the electric storage stack may comprise layers which are formed with a substantially homogeneous thickness on the main surface of the substrate. Additionally or alternatively, the current collector stack and/or the electric storage stack may comprise layers which are formed parallel to one another on the main surface of the substrate. For example, these layers may be formed during a shared manufacturing procedure such as physical vapour deposition (PVD), thereby allowing to conformally deposit the various materials. Consequently, the thickness of the layers may be basically substantially constant over the energy storage portion of the device. Corresponding sections of the corresponding layers may be parallel to one another.

In an embodiment, the following layer sequence may be formed on the substrate: deposition of a barrier stack first (SiO₂/TiO₂), then current collector (Ti/Pt), subsequently the energy storage stack, then a second current collector (i.e. a metallization). The layer sequence may comprise an electrically insulating layer (for instance a silicon oxide layer) for insulating the substrate (for instance a silicon substrate) from the electric storage stack (which may be located above the current collector stack), a decoupling layer (for instance a titanium oxide layer) for preventing contact between the electrically insulating layer and a metallic portion (for instance a titanium layer arranged at a higher level) of the current collector stack, a metallic adhesion layer (for instance the previously mentioned titanium layer) between the decoupling layer and a metallic current collector (which may be located at a higher level), and the metallic current collector (which may comprise platinum). This sequence of layers may be deposited one after the other on top of one another to form a highly efficient stack. This may be followed by the energy storage stack and, if desired or necessary, a further current collector.

An optional insulation stack for electrical insulation and/or adhesion improvement may be provided. However, for embodiments where the substrate is an isolator, the isolation stack is not needed because the substrate is already isolating.

The electric storage stack may comprise a cathode layer (which may be manufactured from LiCoO₂), an electrolyte layer (which may be made from Li₃PO₄) and an anode layer (which may be made from cobalt material). In such an embodiment, the device can be configured as a battery. In an embodiment, in which the device is configured as a capacitor, two capacitor plates (made of an electrically conductive material such as a metal) are separated by a dielectric layer interleaving the two capacitor plates. The electric storage stack can also be inverted. For certain material combinations, the anode is deposited first, then electrolyte, then cathode. However, the order of deposition of cathode/electrolyte and anode can be inversed.

Particularly, the electrolyte layer may be a solid-state electrolyte layer (for instance may be made of Li₃PO₄). In such an embodiment, a full all-solid state device which is not prone to damage even under extreme environmental conditions may be manufactured.

In the following, further exemplary embodiments of the electronic apparatus will be explained. However, these embodiments also apply to the energy storage device and to the method of manufacturing an energy storage device.

The electronic apparatus can be particularly applied to all applications in which an energy supply of a remotely arranged or autarkic operating functional member is required. For example, in a distributed sensor system in an environment which cannot be accessed easily from an exterior position, a long life-time battery with small dimensions may be of particularly advantage. Other examples for electronic apparatuses according to exemplary embodiments are long life-time autonomous applications (for instance a filling level sensor), a lighting control unit (such as a wireless button), a presence and motion detection device (for instance for security applications in private buildings), a building control unit (for instance controlling the energy supply within a building), an autonomous light source (for example for illuminating roads or public places), a green house sensor platform, a wireless add-on sensor (for instance a wireless sensor detecting a temperature) or a medical implantable device (which may be implanted in a physiological object such as a human being to perform specific sensor functions, for instance glucose level detection functions, within the human body).

Next, further exemplary embodiments of the method will be explained. However, these embodiments may also be applied to the electronic device and to the energy storage device.

The method may comprise forming the current collector stack and/or the electric storage stack by physical vapour deposition (PVD). The term “physical vapour deposition” may denote a variety of vacuum deposition techniques and is a general term used to describe any of a variety of methods to deposit thin films by the condensation of a vaporized form of the material onto various surfaces (for instance onto semiconductor wafers). Such coating methods may involve purely physical processes such as high temperature vacuum evaporation or sputter bombardment rather than involving a chemical reaction at the surface to be coated as in chemical vapour deposition.

The method may comprise forming the current collector stack and/or the electric storage stack by PVD. Hence, these key components for the proper functioning of the electric energy supply unit may be manufactured with a very simple process.

The method may comprise covering the steric structure with the current collector stack by substrate biased sputter deposition. Substrate biased sputter deposition may involve firstly covering upper portions of trenches and horizontal surface portions of a patterned substrate with material and subsequently rearranging material from these portions to the side wall portion of the trench to obtain a homogeneous thickness of the deposited material. During resputtering, material from the bottom of the trench may be resputtered on the side wall in order to improve step coverage whereas material near the top of the trench is removed and/or redistributed over the substrate and/or the top part of the side wall of the trenches. By taking this measure, a pronounced topography may be avoided and a high reliability may be ensured. The sputter redeposition (resulting from biased sputtering) may occur simultaneously for both top surfaces and side walls.

The method may comprise manufacturing the energy storage device as a full all-solid state device by physical vapour deposition. Such a device may be manufactured in a compact way without any non-solid state (for instance liquid) components, so that the system can be made robust against damage.

In an embodiment, sputter deposition of multilayers in 3D may be used for example for all solid state batteries. Experimental evidence has been provided by the present inventors describing in detail how a 3D all-solid-state battery stack can be manufactured using PVD (magnetron sputtering and electron beam evaporation) techniques. Additionally, electrical characterization and responses show that (electro)chemically an active 3D battery stack can be realized. Commonly-known PVD deposition techniques can be utilized to deposit multilayers (laminate) onto/into a 3D etched or constructed substrate. Using such processing, 3D capacitors and 3D (solid-state) battery devices can be manufactured. PVD can, for example, be used as a fast and efficient way to manufacture either 3D integrated capacitors, as well as 3D integrated solid-state batteries. In an embodiment, it is explained how a solid-state battery device can be manufactured/deposited onto/into a 3D etched substrate. It may thus be possible to grow battery stacks and multi-layer capacitors in 3D with physical vapour deposition, to grow battery stacks by PVD because the typical dimensions of the materials used for all solid-state lithium ion batteries are more feasible with PVD (due to the higher deposition rate) in contrast to ALD (has very low deposition rate) and CVD (rather low deposition rate), to provide good step coverage of sputtered layers in 3D by applying substrate biased sputter deposition, to grow a solid-state electrolyte layer LiPON in 3D with PVD because LiPON can be properly deposited by PVD. Process integration of LiPON can be enabled by local deposition via a shadow mask. This prevents the use of standard lithography, which, for LiPON-like layers is not straightforward (i.e. easy). It may further be possible to grow barrier layers (current collectors) in 3D because PVD is the preferred technique to deposit (conductive) metallic layers. It may also be possible to grow the full all-solid state battery in one PVD tool.

For any method step, any conventional procedure as known from semiconductor technology may be implemented. Forming layers or components may include deposition techniques like PVD. Removing layers or components may include etching techniques like wet etching, vapour etching, etc., as well as patterning techniques like optical lithography, UV lithography, electron beam lithography, etc.

Embodiments of the invention are not bound to specific materials, so that many different materials may be used. For conductive structures, it may be possible to use metallization structures, silicide structures or polysilicon structures. For semiconductor regions or components, crystalline silicon may be used. For insulating portions, silicon oxide or silicon nitride may be used.

The structure may be formed on a purely crystalline silicon wafer or on an SOI wafer (Silicon On Insulator).

Elements of any process technologies like CMOS, BIPOLAR, BICMOS may be implemented.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 to FIG. 3 show layer sequences obtained during a method of manufacturing an energy storage device according to an exemplary embodiment of the invention, wherein FIG. 3 shows a resulting energy storage device according to an exemplary embodiment of the invention.

FIG. 4 shows an energy storage device according to another exemplary embodiment of the invention.

FIG. 5 is a schematic representation of a full cathode current collector stack comprising SiO₂, TiO₂, Ti and Pt.

FIG. 6 and FIG. 7 show SEM cross-sections of a cathode current collector stack, wherein the full trench, with conformal cathode current collector stack, is shown in FIG. 6, and a more detailed picture, in which the individual layers are denoted, is shown in FIG. 7.

FIG. 8 is a cross-section of a full battery stack manufactured using PVD processes, wherein some battery layers are denoted, and an insert shows the same layer stack on the side-wall of the tapered trench structure.

FIG. 9 is a diagram which shows a galvanostatic response of the PVD-processed 3D solid-state battery stack shown in FIG. 8, wherein the charging current is 10 μA and the discharging current 1 μA.

FIG. 10 shows a diagram illustrating a battery area enhancement as a function of a taper angle.

FIG. 11 shows an electronic apparatus according to an exemplary embodiment of the invention.

### DESCRIPTION OF EMBODIMENTS

The illustration in the drawing is schematical. In different drawings, similar or identical elements are provided with the same reference signs.

Before describing exemplary embodiments in further detail, some basic recognitions will be summarized based on which exemplary embodiments of the invention have been developed. Exemplary embodiments relate to the sputter deposition of multilayers in 3D, for example for all solid state batteries.

The capacity of multi-layer stack capacitors and batteries can be increased significantly by growing these devices in/on three-dimensional (3D) substrates. Examples of 3D configurations are pores, trenches, pillars, honeycombs, etc. The capacity increase depends on the surface enhancement, which is related to the aspect ratio and the number of 3D units.

Conventionally, deposition of multi-layer stacks in 3D can be achieved by Atomic Layer Deposition (ALD) and/or Chemical Vapour Deposition (CVD). With ALD it is possible to deposit layers at low-temperature in 3D configurations with high uniformity and step conformity. However, ALD is slow, still under development, and thus not suitable for industrialization yet. Low Pressure Chemical Vapour Deposition (LPCVD) is generally accepted and widely used in production environments and is also known for its deposition in 3D. For less volatile and more complex materials Metal-Organic Chemical Vapour Deposition (MOCVD) can be considered.

In an embodiment of the invention, it is possible to grow part or the entire stack of lithium all-solid state batteries in 3D with Physical Vapor Deposition (PVD), since it is a relatively simple, fast, cheap and well-established deposition technology, well compatible with battery materials and dimensions. Lithium all-solid-state batteries are based upon the reversible exchange of lithium ions between two electrodes (anode and cathode), which are separated by a solid-state electrolyte, that allows for Li-ion diffusion-migration and prevents electron transport. In addition, diffusion barrier layers may be implemented to prevent the diffusion of lithium species from the electrodes into the substrate. These barrier layers (possibly combined with a current collector) should allow for (external) electron transport from anode (negative electrode) towards cathode (positive electrode) during discharge (and vice versa during charge).

A battery can typically comprises or consist of the following materials:
diffusion barrier layers (current collectors) of titanium nitride (TiN) or tantalum nitride (TaN)
anode of silicon (Si)
solid state electrolyte of lithium phosphorus oxynitride (LiPON: Li_{2.9}PO_{3.3}N_{0.36})
cathode of lithium-cobalt-oxide (LiCoO₂)

A total stack may be in the order of 2 μm (0.1 μm barrier layer; 0.1 μm anode; 0.5 μm solid state electrolyte, 1.0 μm cathode, 0.1 μm current collector). Evidently, other chemistry, leading to 3D-integrated capacitors and batteries, are also possible according to embodiments of the invention. The chemistry mentioned above is just meant as a typical example.

In planar devices, the battery material stack may be deposited by Physical Vapor Deposition (PVD). In an embodiment, the choice for PVD as most preferred technology for 3D batteries will be taken.

A motivation for this will be explained in the following. The layer thickness of the various layers of a lithium all-solid-state battery are such that ALD and CVD are extremely time consuming, especially for the electrolyte and cathode materials (see dimensions above). For the relatively cheap and fast PVD technology it is no problem to grow microns thick battery layers.

In order to obtain good step coverage by PVD, layers can be grown with substrate biased sputtering. In a first (collimated) sputter deposition step, material is deposited onto the bottom of the 3D structures (and partly on the upper side walls). In a second step, material is re-sputtered from the bottom onto the (lower) side walls due to a bias applied to the substrate. If necessary, this sequence can be repeated to increase layer uniformity. Substrate biased deposition of TaN barrier layers matches with the large dimensions of battery stacks.

The most promising solid-state electrolyte LiPON can preferably be deposited by sputtering. This supports the choice for PVD as most preferred deposition technology for 3D batteries. Moreover, process integration of LiPON may be very difficult since LiPON is known to be reactive to water. Patterning of LiPON layers is nurture due to its sensitivity to aqueous solvents present in resist, developer or stripper. An advantage of PVD is that material can be deposited locally by using a shadow mask. Thus, the use of lithography can be circumvented.

Metallic barrier layers such as TiN are most suitable to be deposited by PVD. If the resistivity of the barrier layer is insufficient for electronic conduction it can easily be combined with a pure metallic titanium layer, forming titanium-silicides with the underlying substrate. For PVD that can all be done in one run, whereas deposition of metallic layers by ALD and CVD requires specific precautions (plasma enhancement etc.).

Since all battery layers can possibly be deposited with PVD in 3D, the whole stack can be deposited in one tool without interruption of the vacuum. This will give a significant increase in processing speed.

In the following, referring to FIG. 1 to FIG. 3, a method of manufacturing an energy storage device according to an exemplary embodiment of the invention will be explained.

In order to obtain a layer sequence 100 shown in FIG. 1, a silicon wafer 102 may be processed. Trenches 104 may be etched into a main surface 106 of the silicon substrate 102. Although not shown in the cross-sectional view of FIG. 1, such a trench 104 structure may be formed in one or two dimensions of the main surface 106 of the silicon substrate 102 (for instance in directions perpendicular to and in a paper plane of FIG. 1).

As can be taken from FIG. 1, flat side walls 108 of the trenches 104 and the planar main surface 106 of the silicon wafer 102 enclose an acute angle of about 85°. This may ensure an efficient processing of the expensive silicon wafer 102 with a high area efficiency for providing a battery with a proper capacity.

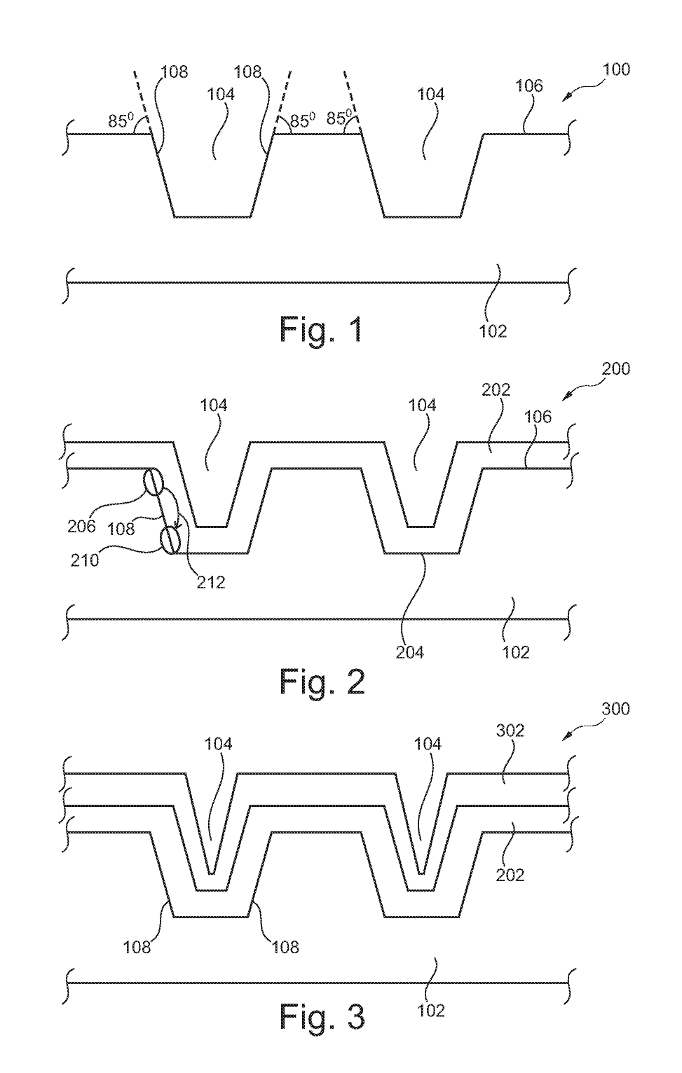

As can be taken from a layer sequence 200 shown in FIG. 2, a current collector stack 202 is formed on the steric structure 104. FIG. 5 shows details of a layer stack constituted by multiple sub-layers of this current collector stack 202, as will be explained below in more detail. The formation of the current collector stack 202 can be performed by physical vapour deposition (PVD).

Optionally, a barrier layer may be deposited on the steric structure 104 before depositing the current collector stack 202.

Although not shown in the figures, the method may comprise covering these trenches 104 with the current collector stack 202 by substrate biased sputter deposition. Referring to FIG. 2, a deposition of material for forming the current collector stack 202 may cover the main surface 106 of the silicon substrate 102 as well as a bottom wall 204 of the trenches 104 as well as upper wall portions 206 of the sidewalls 108 with a thicker layer as compared to lower wall portions 210. In order to equilibrate or balance out thickness differences between the portions 206 and 210, the substrate biased sputter deposition procedure (see reference numeral 212) redirects material from the upper sidewall portion 206 to the lower sidewall portion 210. In this context, a similar procedure may be applied as disclosed in W. F. A. Besling, “Continuity and morphology of TaN barriers deposited by atomic layer deposition and comparison with physical vapour deposition”, Microelectronic Engineering 76, 60 to 69, 2004.

In order to obtain the battery 300 according to an exemplary embodiment shown in FIG. 3, an electric storage stack 302 is formed on the current collector stack 202 by depositing a plurality of layers for forming the electric storage stack by PVD as well. This may involve the manufacture of a cathode and an anode as well as of a solid electrolyte layer between the cathode and the anode.

Optionally, a further current collector layer may be deposited on the electric storage stack 302.

Not only the individual sub-layers of the current collector stack 202 and of the electric storage stack 302 are parallel to one another, but also the current collector 202 and the electric storage stack 302 as a whole. This allows to produce mechanically robust structures.

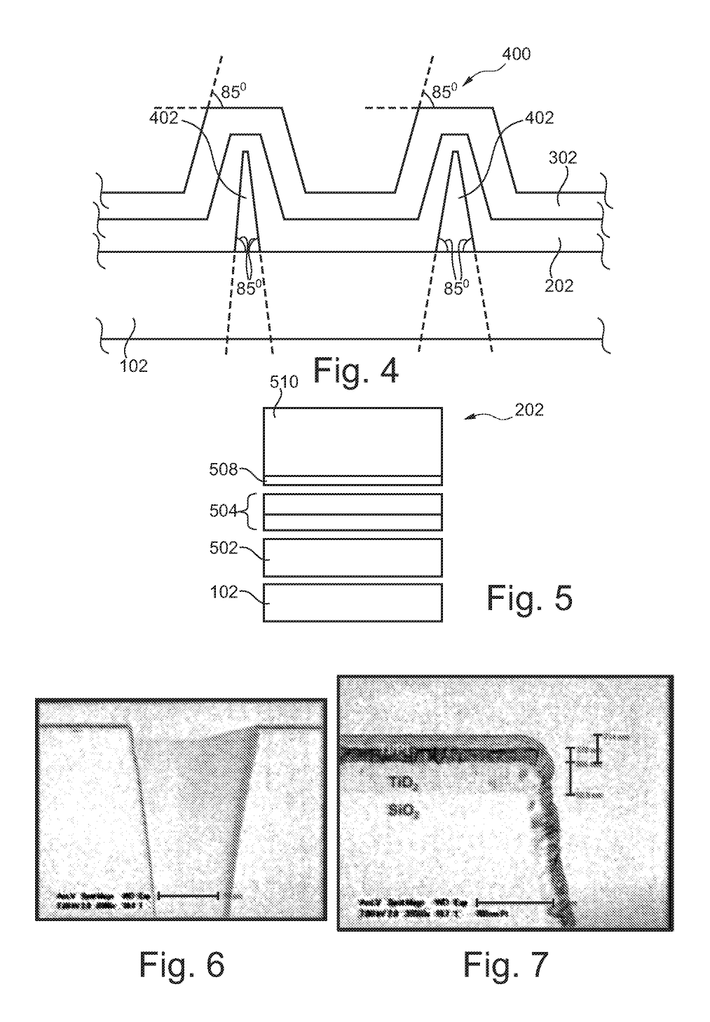

FIG. 4 shows an energy storage device 400 according to another exemplary embodiment of the invention.

In the case of the energy storage device 400, the steric structures are not formed by trenches, but in contrast to this by protrusions or pillars 402 formed on the silicon substrate 102 by deposition, lithography and etching. The subsequent deposition of a current collector stack 202 and an electric storage stack 302 may be performed in a simultaneous manner as explained referring to FIG. 1 to FIG. 3.

Also in this embodiment, acute angles of larger than 80°, particularly of 85°, may be achieved, thereby allowing for a very efficient use of the silicon surface.

FIG. 5 shows details regarding the constitution of the current collector stack 202 on an optional barrier stack.

A silicon substrate 102 is covered with a thermal silicon oxide layer 502. Subsequently, a PVD titanium plus thermal titanium oxide layer 504 is formed. This is followed by a PVD Ti/Pt plus N₂/H₂ treatment, compare reference numerals 508, 510.

In the following, a detailed sequence of producing a battery according to an exemplary embodiment will be explained.

Firstly, a planar Si substrate 102 is etched with the desired 3D features after which the full multistack of various device layers is deposited. In the described embodiment, the type of 3D features chosen is that of a tapered trench 104.

For the sake of clarity this multistack deposition may be broken up into two parts:

1. deposition of the cathode current collector stack 202 after deposition of a barrier stack (comprising SiO₂/TiO₂/Ti/Pt);

2. deposition of the battery layers 302 (LiCoO₂ cathode/Li₃PO₄ solid electrolyte/cobalt top-metallization), which may be followed by the deposition of a further current collector.

Next, details regarding the cathode current collector stack 202 will be mentioned.

The first step is to chemically and electrically isolate the battery stack from the underlying substrate 102.

This is done by means of a SiO₂ layer 502. This layer 502 can be step-conformally grown by means of standard thermal processes (THOX=thermal oxide). Ideally this layer 502 needs to be sufficiently thick (i.e. >50 nm) to prevent electron transport from the battery stack to the silicon substrate 102.

On top of this layer 502, a TiO₂ layer 504 is DC sputtered in 3D. This is done by means of reactive sputtering of Ti metal in an Ar/O₂ plasma. The function of this layer 504 is to prevent contact between the metallic Ti/Pt current collector 508, 510 and the SiO₂ 502, as well as a first adhesion layer.

Subsequently a very thin layer of metallic Ti 508 is deposited by means of DC sputtering in Ar atmosphere. This acts as an adhesion layer between the TiO₂ 504 and the Pt 510. Then, the Pt current collector 510 (cathode current collector) is deposited using DC sputtering.

This entire stack 202 is shown schematically in FIG. 5.

SEM investigation reveals that the same stack can be deposited nicely, and reasonable step-conformally, in 3D features (in this case tapered trench structures) using the above mentioned techniques.

This can be seen well in FIG. 6 and FIG. 7.

It has been experimentally determined that this cathode current collector stack can withstand all processing steps needed to deposit a chemically active battery stack onto it.

Next, details regarding the battery stack 302 will be mentioned.

After the cathode current collector stack 202 has been deposited, deposition of the battery stack 302 is next. This stack 302 comprises the subsequent deposition of the cathode (LiCoO₂), the solid electrolyte (Li₃PO₄) and the top metallization (Cobalt).

It should be mentioned that between the cathode and electrolyte deposition a thermal anneal of the cathode can be performed to increase its electrochemical activity. In this example said anneal treatment was omitted.

In detail:
The LiCoO₂ layer is deposited using RF magnetron sputtering using a LiCoO₂ composite target in a Ar/O₂ plasma.
The Li₃PO₄ layer is deposited using RF magnetron sputtering using a Li₃PO₄ composite target in a pure Ar plasma.
The Cobalt top metallization is done with electron-beam evaporation using a cobalt target in high vacuum.

FIG. 8 shows a SEM cross-section of the complete stack: SiO₂/TiO₂/Ti/Pt/LiCoO₂/Li₃PO₄/Co. The battery layers are denoted in FIG. 8. The insert in FIG. 8 shows the layers stack on the side-wall of the tapered trench.

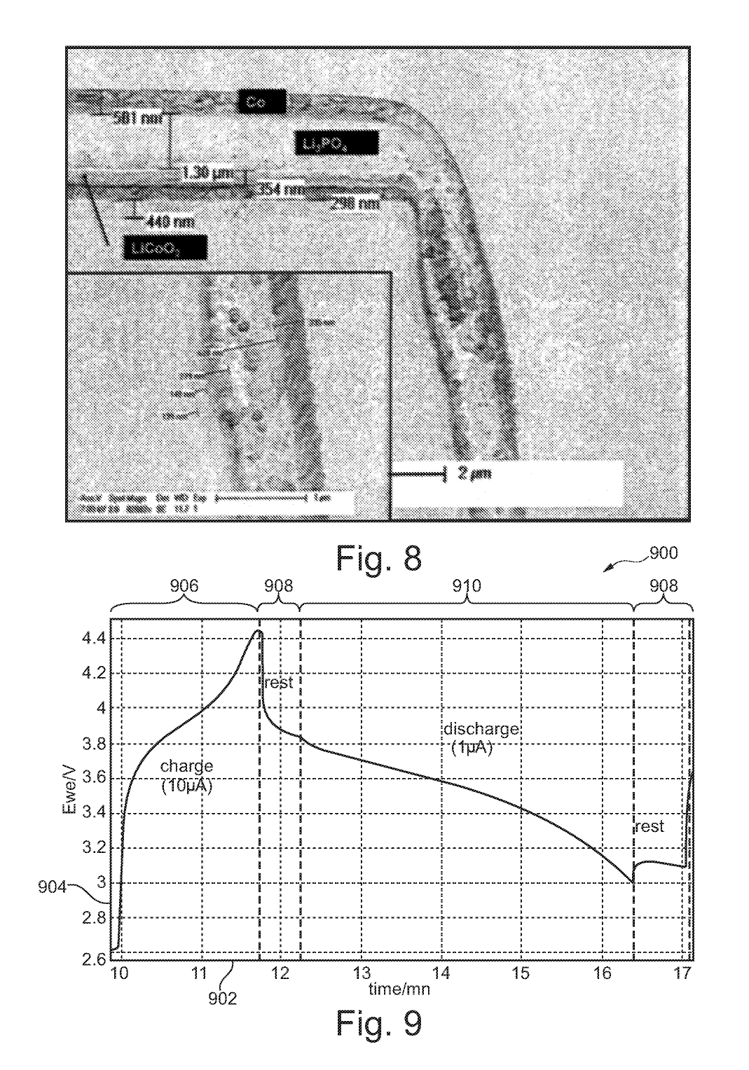

FIG. 9 shows a diagram 900 having an abscissa 902 along which the time is plotted. Along an ordinate 904, the energy is plotted.

During a charging time interval 906, the battery shown in FIG. 8 is charged. During a resting phase 908, the system is idle. During a discharging phase 910, the battery shown in FIG. 8 is discharged, and this is followed by a further rest phase 908.

To confirm whether the 3D solid-state battery works in practice, electrical measurements were performed. FIG. 9 shows the galvanostatic response of the stack when subjected to a constant charge current (10 μA) and discharge current (1 μA). A charging current of 10 μA is used until a cut-off potential is reached of 4.5 V, followed by a rest period 908. Subsequently, the stack is discharged with 1 μA until a certain cut-off voltage is obtained (again followed by a rest period 908).

It is evident from FIG. 9 that clear and distinct electrical responses can be detected during charge and discharge stages that can be directly linked to the (reversible) electrochemical conversion of a stack comprising amorphous LiCoO₂. This shows that it is feasible to manufacture 3D solid-state batteries using PVD techniques in appropriate 3D-etched substrates.

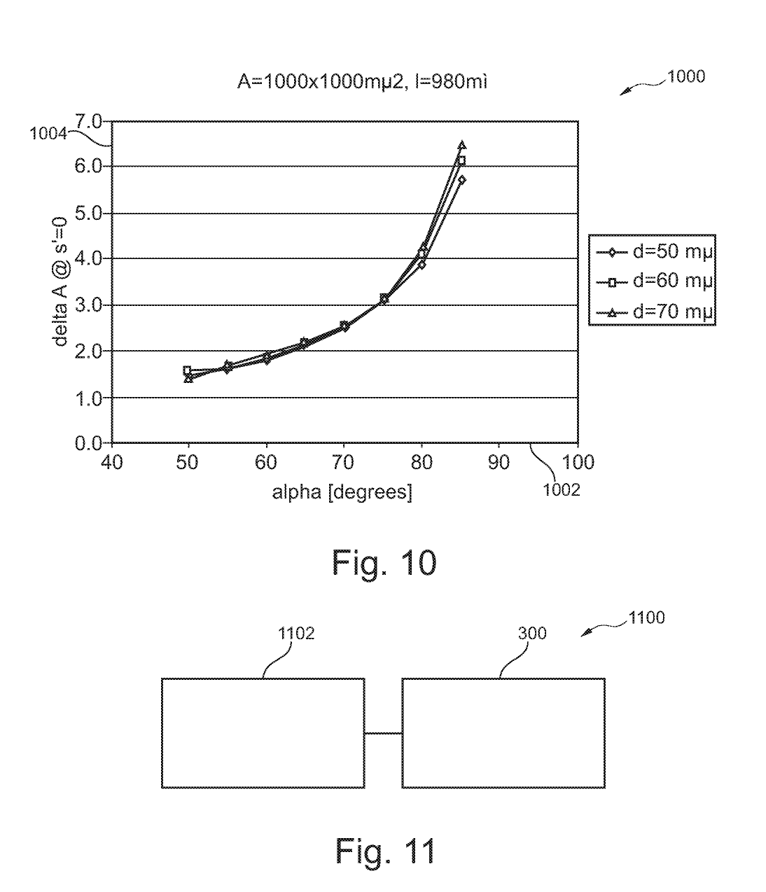

FIG. 10 shows a diagram 1000 having an abscissa 1002 in which a slanting angle of side walls (compare reference numeral 108, 85°) is plotted. Along an ordinate 1004, an effective area is plotted. As can be taken from FIG. 10, the curve dramatically increases above 80°.

The graph of FIG. 10 shows the battery area enhancement as a function of the taper angle. According to this graph, the tapering angle needs to be larger than 80 degrees in order to realize significant area enhancement. A sufficient area enlargement is achieved for angles larger than 85 degrees, reaching a maximum at 90°. Using 85 degree angle, the present inventors already have realized batteries in 3D using PVD that work. Hence, a proper area enlargement is achieved for angles around 85 degrees whereas maximum area enlargement is obtained for 90 degree angle.

FIG. 11 shows an electronic apparatus 1100 according to an exemplary embodiment of the invention.

The electronic apparatus 1100 comprises a functional component 1102 such as an autarkic sensor adapted for providing an electronic sensor function when being powered with electric energy. An energy storage device 300 as explained above may be configured as a battery for storing the electric energy for powering the functional sensor component 1102.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. An energy storage device, the device comprising
a substrate;
a steric structure formed on and/or in a main surface of the substrate;
a current collector stack formed on the steric structure;
an electric storage stack formed on the current collector stack;
wherein side walls of the steric structure and the main surface of the substrate enclose an acute angle of equal or more than 80 degrees.

2. The device according to claim 1, wherein the steric structure comprises at least one trench, particularly at least one rectangular or trapezoidal or ovaltrench, formed in the substrate.

3. The device according to claim 1, wherein the steric structure comprises at least one protrusion, particularly at least one rectangular or trapezoidal protrusion, formed on the substrate.

4. The device according to claim 1, wherein the current collector stack and/or the electric storage stack comprises layers which are formed with a substantially homogeneous thickness and/or formed parallel to one another on the main surface of the substrate.

5. The device according to claim 1, further comprising an electrically insulating layer for insulating the substrate from the electric storage stack and a decoupling layer for preventing contact between the electrically insulating layer and the current collector stack, wherein the electrically insulating layer and the decoupling layer are arranged between the substrate and the current collector stack.

6. The device according to claim 1, further comprising an additional current collector on the electric storage stack.

7. The device according to claim 1, wherein the electric storage stack comprises a cathode layer, an electrolyte layer, and an anode layer.

8. The device according to claim 7, wherein the electrolyte layer is a solid-state electrolyte layer.

9. The device according to claim 1, adapted as a full all-solid state device.

10. The device according to claim 1, adapted as one of a battery and a capacitor.

11. The device according to claim 1, monolithically integrated in and/or on the substrate.

12. The device according to claim 1, wherein the substrate is a semiconductor substrate, particularly one of the group consisting of a group IV semiconductor substrate, a silicon substrate, a germanium substrate, a group III-group V semiconductor substrate, and a GaAs substrate.

13. An electronic apparatus, comprising
a functional component adapted for providing an electronic function when being powered with electric energy;
an energy storage device according to claim 1 for storing the electric energy for powering the functional component.

14. The electronic apparatus according to claim 13, adapted as one of the group consisting of a long-lifetime autonomous application, a lighting control unit, a presence detection device, a motion detection device, a building control unit, a building energy control unit, an autonomous light source, a green house sensor platform, a wireless add-on sensor, and a medical implantable device.

15. A method of manufacturing an energy storage device, the method comprising
forming a steric structure on and/or in a main surface of a substrate;
forming a current collector stack on the steric structure;
forming an electric storage stack on the current collector stack;
wherein side walls of the steric structure and the main surface of the substrate enclose an acute angle of more than 80 degrees.

16. The method according to claim 15, comprising forming the current collector stack and/or the electric storage stack by physical vapour deposition, particularly by magnetron sputtering and/or electron beam evaporation.

17. The method according to claim 15, comprising covering the steric structure with the current collector stack by substrate biased sputter deposition.

18. The method according to claim 15, comprising manufacturing the energy storage device as a full all-solid state device by physical vapour deposition.
